(19) United States
(12) Patent Application Publication
(10) Pub. No.: US 2010/0258938 A1
(43) Pub. Date: Oct. 14, 2010

(54) SUBSTRATE AND SEMICONDUCTOR DEVICE

(75) Inventors: Teppei Ito, Tokyo (JP); Hitoshi Kawaguchi, Tokyo (JP); Hiroyuki Tanaka, Tokyo (JP)

Correspondence Address: Ditthavong Mori & Steiner, P.C., 918 Prince Street, Alexandria, VA, 22314, US

(73) Assignee: SUMITOMO BAKELITE CO., LTD., Tokyo (JP)

(21) Appl. No.: 12/742,926

(22) PCT Filed: Dec. 5, 2007
(86) PCT No.: PCT/JP2007/001349

§ 371 Date: May 14, 2010

(51) Int. Cl. H01L 23/498; H05K 1/03

(52) U.S. Cl. 257/737; 174/258; 257/E23.068

(57) ABSTRACT

A substrate (3) has a build-up layer in which insulating layers containing a resin and conductor interconnect layers (312) are alternately laminated and the conductor interconnect layers (312) are mutually connected through the conductor layer formed in a via-hole of the insulating layer. A conductor interconnect layer (312D) arranged on the outermost surface side of a substrate among the conductor interconnect layers (312) has a plurality of signal lines (312D1) formed in a signal line arrangement area (A) and extended in a predetermined direction. When αsig-x represents a coefficient of thermal expansion in a direction substantially parallel to the signal lines (312D1) in the signal line arrangement area (A) having the signal lines (312D1) as determined by a laser speckle method and αsig-y represents a coefficient of thermal expansion in a direction substantially orthogonal to the signal lines as determined by a laser speckle method, a dependence rate in the signal line direction of a coefficient of thermal expansion represented by the following equation is 25 or less.

Dependence rate in the signal line direction of the coefficient of thermal expansion=(|αsig-y−αsig-x|/αsig-x)×100.

### TECHNICAL FIELD

The present invention relates to a substrate and a semiconductor device.

### BACKGROUND ART

A conventional-used semiconductor device has a structure in which a semiconductor element (semiconductor chip) is mounted on a substrate.

A substrate for such a semiconductor device generally has a core layer and a build-up layer (for example, see Patent Reference No. 1).

Patent Reference No. 1: Japanese published unexamined application No. 2005-191243.

### DISCLOSURE OF THE INVENTION

When such a conventional substrate is heated, the substrate may warp. Warpage in the substrate may reduce reliability in connection with a semiconductor element.

An objective of the present invention is thus to provide a substrate with which generation of warpage can be reduced, and a semiconductor device with such a substrate.

Our investigation has suggested the following cause for warpage in a substrate.

Among conductor interconnect layers of build-up layers in a substrate, a conductor interconnect layer in the outermost surface side of the substrate has a plurality of signal lines.

Our investigation has demonstrated that in a signal line arrangement area having a plurality of signal lines, a coefficient of thermal expansion is relatively smaller in a direction parallel to the signal lines while being relatively larger in a direction orthogonal to the signal lines.

In the direction parallel to the signal lines, signal lines are continuously extended and the signal lines probably strongly constrain an underlying insulating layer. It presumably makes a coefficient of thermal expansion relatively smaller in the direction parallel to the signal lines.

On the other hand, in the direction orthogonal to the signal lines, signal lines are intermittently and discontinuously arranged with predetermined intervals, so that presumably, the signal lines cannot strongly constrain the underlying insulating layer. It can be speculated that a coefficient of thermal expansion in the direction orthogonal to the signal lines becomes relatively larger.

Probably, warpage in a substrate is considerably influenced by the difference in a coefficient of thermal expansion between the directions parallel to the signal lines and orthogonal to the signal lines in the signal line arrangement area, and thus, seems to influence reliability in connection with a semiconductor element.

According to the present invention, there is provided a substrate comprising a build-up layer in which resin-containing insulating layers and conductor interconnect layers are alternately laminated and said conductor interconnect layers are mutually connected through a conductor layer formed in a via-hole in said insulating layer, wherein among said conductor interconnect layers, a conductor interconnect layer formed in the outermost surface side of the substrate includes a plurality of signal lines extending substantially in parallel with each other and when αsig-x represents a coefficient of thermal expansion in a direction substantially parallel to said signal lines in the signal line arrangement area having the plurality of signal lines as determined by a laser speckle method and αsig-y represents a coefficient of thermal expansion in a direction substantially orthogonal to said signal lines as determined by a laser speckle method, a dependence rate in the signal line direction of a coefficient of thermal expansion represented by the following equation is 25 or less.

Dependence rate in the signal line direction of the coefficient of thermal expansion=(|αsig-y−αsig-x|/αsig-x)×100

Here, a signal line arrangement area is an area where a plurality of signal lines substantially extend in parallel with each other. When there are a plurality of areas having signal lines, a dependence rate in the signal line direction of a coefficient of thermal expansion in at least one signal line arrangement area has only to be 25 or less.

Furthermore, it is preferable that in the signal line arrangement area, 5 or more of signal lines are arranged substantially in parallel with each other.

As described above, we have found that there is a difference between coefficient of thermal expansions in a direction parallel to the signal lines and in a direction orthogonal to the signal lines in the signal line arrangement area and that warpage in the substrate can be reduced when a value calculated by the above equation is 25 or less.

That is, according to the present invention, a dependence rate in the signal line direction of a coefficient of thermal expansion is 25 or less, so that a difference between coefficient of thermal expansions in a direction parallel to the signal lines and in a direction orthogonal to the signal lines in the signal line arrangement area can be reduced and warpage in the substrate can be reduced.

Here, αsig-y is preferably 2.5 ppm/° C. or more and 26 ppm/° C. or less.

Furthermore, αsig-x can be also reduced by adjusting a dependence rate in the signal line direction of the coefficient of thermal expansion in the signal line arrangement area to 25 or less and reducing an αsig-y to 2.5 ppm/° C. or more and 26 ppm/° C. or less. Deviation of the signal line arrangement area in directions orthogonal to and deviation of the signal line arrangement area parallel to the signal lines can be reduced. Thus, warpage in the substrate can be more reliably reduced.

A substrate according to the present invention may be a substrate having only a build-up layer or a substrate having a core layer in which a throughhole filled with a conductor layer is formed within the insulating layer and the conductor layer in the throughhole is connected to the conductor interconnect layer in the build-up layer.

The resin in the insulating layer in said build-up layer preferably contains a cyanate resin. Furthermore, it is preferable that a substrate has a core layer in which a throughhole filled with a conductor layer is formed within the insulating layer and the conductor layer in the throughhole is connected to the conductor interconnect layer in the build-up layer, and the resin in said insulating layer in said core layer contains a cyanate resin.

Furthermore, said cyanate resin is preferably a novolac-type cyanate resin.

A dependence rate in the signal line direction of a coefficient of thermal expansion can be reliably reduced by using a cyanate-containing resin, particularly a novolac-type cyanate resin as the resin in the insulating layer.

Among the insulating layers in said build-up layer, at least one insulating layer preferably contains a resin and a sheet base material supporting the resin.

Examples of a sheet base material include fiber base materials such as organic fibers including carbon fiber, glass fiber, synthetic fiber and paper and resin films. The use of an insulating layer having a sheet base material can improve strength of a build-up layer and furthermore, warpage in a substrate can be reduced.

The phrase “supporting a resin by a sheet base material” as used herein means that a resin layer is supported and reinforced by a sheet base material, including impregnation of a sheet base material with a resin and direct lamination of a resin layer on a sheet base material.

Furthermore, said insulating layer having said sheet base material is preferably disposed in the outermost surface layer in said build-up layer.

Thus, warpage in a substrate can be reliably prevented.

Furthermore, a thickness of said sheet base material is preferably 5 μm or more 30 μm or less.

A thickness of the sheet base material of more than 30 μm is unfavorable because the overall substrate becomes too thick. When a thickness of the sheet base material is less than 5 μm, the resin may be insufficiently reinforced.

A thickness of said substrate is preferably 800 μm or less.

Furthermore, according to the present invention, there can be provided a semiconductor device comprising a substrate, a semiconductor element mounted on said substrate, a bump connecting said substrate with said semiconductor element, and an underfill filling the periphery of said bump, wherein said substrate is any of the above-mentioned substrates and said underfill is made of a resin material having an elastic modulus of 1.5 GPa or more and 12 GPa or less at room temperature.

Furthermore, said semiconductor element preferably includes a silicon substrate, an insulating film containing a low-dielectric constant film with a specific dielectric constant of 3.3 or less which is formed on the silicon substrate, and an interconnection formed in said insulating film.

Conventionally, heating a substrate with a semiconductor element being mounted has sometimes caused warpage in the substrate, leading to cracks in, for example, an interface between a bump and the substrate.

Thus, it has been proposed that the periphery of the bump is filled with an underfill with a high elastic modulus, but an underfill with a high elastic modulus may cause damage on a low-k layer in the semiconductor element.

In contrast, a semiconductor device of the present invention uses a substrate with warpage being reduced, so that crack formation can be prevented in, for example, an interface between a bump and a substrate. It can eliminate the necessity of using an underfill with a high elastic modulus, and thus an underfill with a low elastic modulus which is made of a resin material with an elastic modulus of 1.5 GPa or more and 12 GPa or less, can be used, resulting in prevention of damage on a low-k layer in the semiconductor element.

According to the present invention, there is provided a substrate by which warpage can be reduced and a semiconductor device having such a substrate.

The above-mentioned and the other objectives, features and advantages of the invention will be further understood with reference to the following suitable embodiments and the accompanying drawings.

### BRIEF DESCRIPTION OF THE DRAWINGS

FIG. 1 is a cross-sectional view according to an embodiment of the present invention.

FIG. 2 is a plan view of a substrate.

FIG. 3 is a plan view showing a conductor interconnect layer in a substrate.

FIG. 4 is a plan view illustrating another conductor interconnect layer in a substrate.

FIG. 5 is a cross-sectional view showing a process for manufacturing a substrate.

FIG. 6 is a cross-sectional view showing a process for manufacturing a substrate.

FIG. 7 is a schematic view illustrating a semiconductor device.

FIG. 8 is a cross-sectional view showing a variation of a substrate according to the present invention.

FIG. 9 shows a temperature-displacement rate in a signal line arrangement area in a substrate.

### BEST MODE FOR CARRYING OUT THE INVENTION

There will be described embodiments of the present invention with reference to the drawings.

There will be described embodiments of the present invention with reference to the drawings.

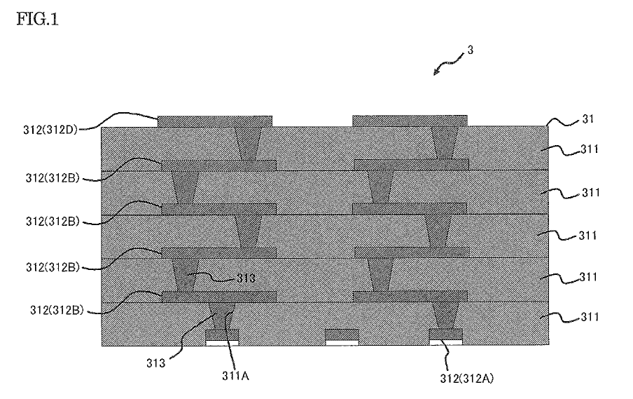

FIG. 1 shows a substrate 3 according to this embodiment.

The substrate 3 has a build-up layer 31 in which insulating layers 311 containing a resin and conductor interconnect layers 312 are alternately laminated and the conductor interconnect layers 312 are mutually connected through a conductor layer 313 formed in a via-hole in the insulating layer 312.

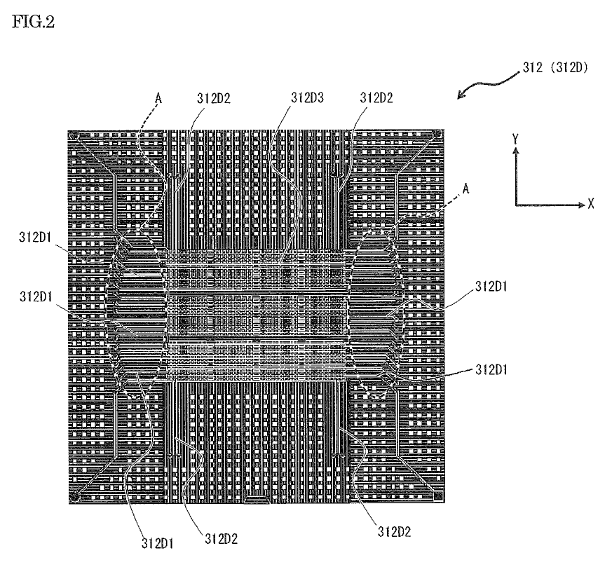

As shown in FIG. 2, a conductor interconnect layer 312D arranged on the outermost surface side of a substrate among the conductor interconnect layers 312 has a plurality of signal lines 312D1 formed in a signal line arrangement area A and extended in a predetermined direction.

When αsig-x represents a coefficient of thermal expansion in a direction substantially parallel (X-direction) to the signal lines 312D1 in the signal line arrangement area A having the signal lines 312D1 as determined by a laser speckle method and αsig-y represents a coefficient of thermal expansion in a direction substantially orthogonal (Y-direction) to the signal lines as determined by a laser speckle method, a dependence rate in a signal line direction of the coefficient of thermal expansion expressed by the following formula is 25 or less.

Dependence rate in the signal line direction of the coefficient of thermal expansion=(|αsig-y−αsig-x|/αsig-x)×100 Equation 1

There will be more detailed the substrate 3.

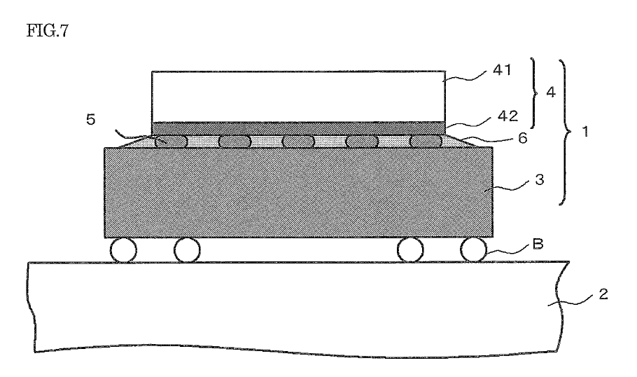

On the substrate 3, a semiconductor element (semiconductor chip) 4 is flip-chip mounded through a bump 5 (see FIG. 7).

This substrate 3 has, as shown in FIG. 1, the build-up layer 31 in which the resin-containing insulating layers 311 and the conductor interconnect layers 312 are alternately laminated. For example, in this embodiment, the plurality of insulating layers 311 (5 layers) and the plurality of conductor interconnect layers 312 (6 layers) are alternately laminated. This substrate 3 does not have a core layer.

This substrate 3 has a thickness of 800 μm or less, preferably 500 μm or less.

In this embodiment, the insulating layer 311 is not a prepreg where a fabric made of carbon fiber or glass fiber or fibers aligned in one direction is impregnated with any of various resins, but is made of a resin composition alone. That is, the insulating layer 311 is not reinforced by fiber such as carbon fiber and glass fiber.

Examples of a resin constituting the insulating layer 311 include epoxy resins, BT resins and cyanate resins. Among others, a cyanate resin is preferable. Examples of a cyanate resin include novolac-type cyanate resins, bisphenol-A type cyanate resins, bisphenol-E type cyanate resins and tetramethylbisphenol-F type cyanate resins. Among others, a novolac-type cyanate resin is preferable.

A novolac-type cyanate resin represented by the following formula can be used:

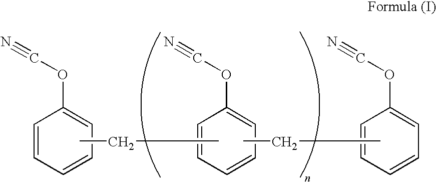

wherein n represents an integer.

Such a novolac-type cyanate resin can be, for example, produced by reacting a novolac-type phenol with a suitable compound such as cyanogen chloride and cyanogen bromide.

The novolac-type cyanate resin has, for example, an weight-average molecular weight of preferably 500 to 4500, more preferably 600 to 3000.

When the weight-average molecular weight is less than 500, mechanical strength may be deteriorated. When the weight-average molecular weight is more than 4500, a resin component is cured so rapidly that storage stability may be deteriorated.

Alternatively, the cyanate resin may be a prepolymer for a cyanate resin. A cyanate resin or prepolymer may be used alone or a cyanate resin and a prepolymer may be combined. Here, a prepolymer is generally a product from a cyanate resin by, for example, trimerization by heating. There are no particular restrictions to a prepolymer, and, for example, a prepolymer having a trimerization rate of 20 to 50% by weight can be used. This trimerization rate can be determined using, for example, an infrared spectrometer.

Alternatively, the cyanate resin may contain, for example, an epoxy resin, a phenoxy resin or the like. A preferable epoxy resin contains a biphenylalkylene backbone.

The insulating layer 311 may be a resin composition containing a variety of resins supported by a sheet base material such as a fabric of carbon fiber or glass fiber.

That is, the insulating layer 311 may be reinforced by a fiber base material such as a fiber base material of carbon fiber or glass fiber or a resin film.

Examples of such a sheet base material include fiber base materials including glass fiber base materials such as glass woven fabrics and glass unwoven fabrics; polyamide resin fibers such as polyamide resin fibers, aromatic polyamide resin fibers and wholly aromatic polyamide resin fibers; polyester resin fibers such as polyester resin fibers, aromatic polyester resin fibers and wholly aromatic polyester resin fibers; synthetic fiber base materials as a woven fabric or unwoven fabric made of, for example, polyimide resin fiber and fluororesin fiber as a main component; organic fiber base materials including paper base materials containing, for example, craft paper, cotton linter paper or a mixed paper of linter and craft pulp; and resin films such as polyester and polyimide. Among these, a fiber base material is preferably used. When a fiber base material is used, a resin is disposed such that it fills spaces between fibers in the fiber base material. The fiber base material is preferably a glass fiber base material. Thus, strength of the insulating layer can be improved. Furthermore, a thermal expansion coefficient of the insulating layer can be reduced.

Examples of a glass constituting such a glass fiber base material include E glass, C glass, A glass, S glass, D glass, NE glass, T glass and H glass. Among these, S glass or T glass is preferable. Thus, the thermal expansion coefficient of the glass fiber base material can be reduced, and therefore, a thermal expansion coefficient of the insulating layer 311 can be reduced. Thus, the dependence rate in the signal line direction of the coefficient of thermal expansion represented by Equation (1) can be reliably 25 or less.

A thickness of the sheet base material is, but not limited to, preferably 30 μm or less, particularly preferably 25 μm or less, most preferably 10 to 20 μm when a thin insulating layer is produced. When a thickness of the sheet base material is 30 μm or less, there is good balance between thinning of the substrate and strength. Furthermore, processability and reliability in interlayer connection are improved.

A thickness of the sheet base material is preferably 5 μm or more. When a thickness of the sheet base material is 5 μm or more, the insulating layer 311 can be reliably reinforced.

Furthermore, when the insulating layer 311 contains a sheet base material, all of the insulating layers 311 can contain a sheet base material or, for example, some of the insulating layers 311 may contain a sheet base material.

Here, the insulating layer 311 containing a sheet base material is preferably disposed in the build-up layer in the outermost surface layer side of the substrate. By disposing the insulating layer 311 containing a sheet base material in the build-up layer in the outermost surface layer side of the, overall warpage of the substrate can be reliably minimized.

It can be acceptable that the insulating layer containing a sheet base material is used in an area other than the outermost surface layer of the build-up layer in the substrate.

The insulating layer where a resin is supported by a sheet base material can be formed, for example, by laminating a resin layer on the sheet base material to form the insulating layer or impregnating the sheet base material with the resin layer.

Among the conductor interconnect layers 312, the conductor interconnect layer 312D disposed in the outermost surface side is, for example, a copper interconnect layer. This conductor interconnect layer 312D has, as shown in FIG. 2, a plurality of (5 or more) signal lines 312D1 extending in X direction. The plurality of signal line 312D1 extend in substantially parallel to each other.

Among the plurality of signal lines 312D1, some of the signal lines 312D1 have an end bending to Y direction. The term, “a direction substantially parallel to the signal line 312D1 in the signal line arrangement area A” means a direction parallel to an extending direction of the signal line 312D1 except the end of the signal line 312D1. In other words, it is a direction parallel to a part of the signal line 312D1 accounting for a half or more of the length of the signal line 312D1.

The conductor interconnect layer 312D also has a plurality of signal line 312D1 extending in the Y-axis direction. The number of the signal lines 312D1 is larger than that of the signal lines 312D1, and the conductor interconnect layers 312D1 are arranged more densely than the signal lines 312D1.

Furthermore, the conductor interconnect layer 312D has amounting part 312D1 for mounting a semiconductor element 4 in the center. Signal lines 312D1 and 312D1 are connected to this mounting part 312D1.

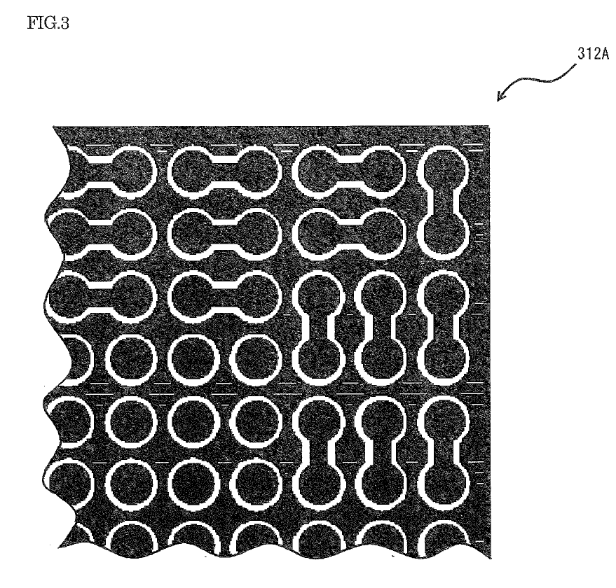

Among the conductor interconnect layers 312, a conductor interconnect layer 312A as the lowest layer is, for example, a copper interconnect layer, which has the structure shown in FIG. 3. In FIG. 3, the black part indicates the copper interconnection.

A copper-remaining rate of the conductor interconnect layer 312A (a proportion occupied by the conductor interconnect layer 312A covering the insulating layer 311) is 80%.

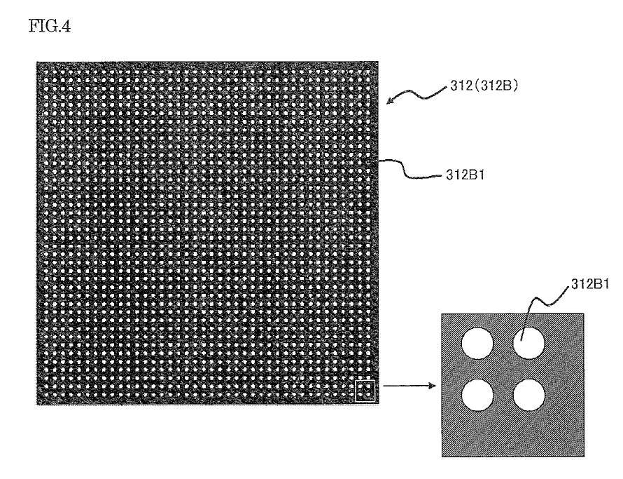

A conductor interconnect layer 312B disposed in the conductor interconnect layer 312A is also, for example, a copper interconnection layer having a planar shape as shown in FIG. 4. There are formed a plurality of substantially circular openings 312B1. The right-bottom figure in FIG. 4 is an enlarged view of the conductor interconnect layer 3125.

A diameter of the opening 312B1 is, for example, 500 μm. A copper-remaining rate of this conductor interconnect layer 312A is generally 60 to 90%, preferably 75 to 85%.

Here, a pair of the conductor interconnect layers 312 disposed sandwiching the insulating layer 311 are connected through the copper conductor layer 313 formed in a via-hole 311A in the insulating layer 311.

As described above, when αsig-x represents a coefficient of thermal expansion in a direction substantially parallel (X-direction) to the signal lines 312D1 in the signal line arrangement area A in such a substrate 3 as determined by a laser speckle method and αsig-y represents a coefficient of thermal expansion in a direction substantially orthogonal (Y-direction) to the signal lines as determined by a laser speckle method, the dependence rate in the signal line direction of the coefficient of thermal expansion represented by the following equation is 25 or less and 0 or more.

Dependence rate in the signal line direction of the coefficient of thermal expansion=(|αsig-y−αsig-x|/αsig-x)×100

The dependence rate in the signal line direction of the coefficient of thermal expansion is preferably 15 or less. With the dependence rate in the signal line direction of 15 or less, warpage of the surface of the substrate 3 can be reliably reduced.

Here, αsig-y is 2.5 ppm/° C. or more and 26 ppm/° C. or less. It is particularly preferably 4 ppm/° C. or more and 22 ppm/° C. or less.

With αsig-y of 26 ppm/° C. or less, particularly 22 ppm/° C. or less, warpage after mounting a semiconductor element can be more reduced.

Furthermore, αsig-x is preferably 2.5 ppm/° C. or more and 26 ppm/° C. or less. It is particularly 4 ppm/° C. or more and 22 ppm/° C. or less.

With αsig-x of 26 ppm/° C. or less, particularly 22 ppm/° C. or less, warpage after mounting a semiconductor element can be more reduced.

Here, αsig-x as a coefficient of thermal expansion in a direction substantially parallel (X-direction) to the signal lines 312D1 in the signal line arrangement area A and αsig-y as a coefficient of thermal expansion in a substantially orthogonal direction (Y-direction) can be determined as follows.

Here, a laser speckle method is used for determining coefficient of thermal expansions αsig-x and αsig-y.

While warming the substrate 3 from 25° C. to 260° C., the signal line arrangement area A in the substrate 3 is irradiated with a laser beam from an Ar laser source of a laser speckle measurement apparatus (DANTEC ETTEMEYER, trade name: 3D-ESPI System Q-300). Next, a speckle pattern is obtained from a light reflected by the signal line arrangement area A. From this variation in a speckle pattern, a displacement amount in the signal line arrangement area A in the substrate 3 is calculated. Then, a graph of a temperature-displacement amount where a horizontal axis is a temperature and a vertical axis is a displacement amount in X-direction or Y-direction is approximated to a straight line connecting room temperature (25° C.) and 260° C., and coefficient of thermal expansions αsig-x and αsig-y are calculated, respectively.

The substrate 3 described above is produced as follows.

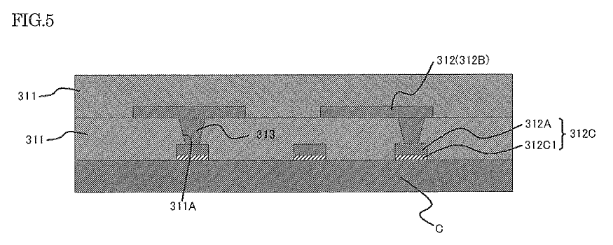

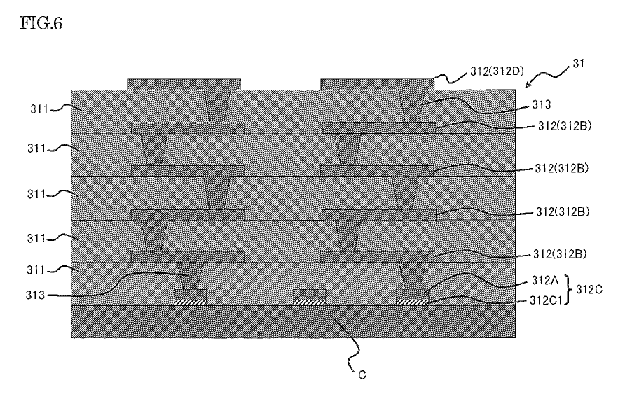

The procedure will be described with reference to FIGS. 5 and 6.

First, a conductor interconnect layer 3120 is formed on the surface of a copper plate C with a predetermined thickness in a predetermined pattern.

This conductor interconnect layer 312C has a two-layer structure of a first metal layer 312C1 and the second metal layer 312A laminated on the first metal layer 312C1, which is to be the conductor interconnect layer 312A as described above.

The first metal layer 312C1 is, for example, made of nickel while the second metal layer 312A is made of copper as described above. The pattern of the conductor interconnect layer 312C is as shown in FIG. 3.

Subsequently, the surface of the copper plate C and the conductor interconnect layer 312C are roughened by an etchant and the insulating layer 311 is laminated on the conductor interconnect layer 3120 (the step of lamination).

The via-hole 311A is formed in a predetermined position in the insulating layer 311 by laser (the step of forming a via-hole).

Next, by a semi-additive method are formed the conductor layer 313 in the via-hole 311A and the conductor interconnect layer 312B as shown in FIG. 4.

Specifically, a copper film (seed film) is formed to about 1 μm over the whole surface of the insulating layer 311 by nonelectrolytic plating. Next, on the insulating layer 311 is formed a photoresist (mask) in a predetermined pattern. Then, a plating film is formed in a part without being masked (for example, via-hole 311A) by electrolytic plating. Thus, in the via-hole 311A are formed the conductor layer 313 and furthermore the conductor interconnect layer 312B (the step of forming a conductor layer 313 and a conductor interconnect layer 312B). Then, the mask is removed and additionally, the seed film exposed after the mask removal is removed.

Then, the conductor interconnect layer 312B is roughened and the steps of lamination, forming a via-hole, and forming a conductor layer 313 and a conductor interconnect layer 312B are conducted. After repeating the procedure, the conductor layer 313 and the conductor interconnect layer 312D are formed as in the step of forming a conductor layer 313 and a conductor interconnect layer 312B.

Thus, as shown in FIG. 6, there is provided the build-up layer 31 having the plurality of insulating layers 311 (5 layers) and the plurality of conductor interconnect layers 312 (6 layers).

Subsequently, an etching resist film (not shown) is formed on the uppermost conductor interconnect layer 312D. Then, the copper plate C is removed by etching.

Furthermore, the first metal layer 312C1 is removed by a nickel removing liquid. Thus, there is provided the substrate 3 as shown in FIG. 1.

The substrate 3 thus obtained is used in a semiconductor device 1 as shown in FIG. 7.

### Semiconductor Device

This semiconductor device 1 has the substrate 3, a semiconductor element 4 mounted on the substrate 3, a bump 5 connecting the substrate 3 with the semiconductor element 4, and an underfill 6 filling the periphery of the bump 5.

This semiconductor device 1 is mounted on the substrate 2 via a bump B.

The underfill 6 is made of a resin material having an elastic modulus of 1.5 GPa or more and 12 GPa or less at room temperature.

### Semiconductor Chip

The semiconductor chip 4 has, as shown in FIG. 7, an interconnect layer 42 as a so-called low-k layer on a silicon substrate 41. It may have various functions such as, but not limited to, logic devices, memory devices and combination thereof.

The low-k layer is formed as an interlayer dielectric. Here, the low-k layer means a film with a specific dielectric constant of 3.3 or less. Examples of the low-k layer include organic layers such as SiOC, MSQ (methylsilsesquioxane) and benzocyclobutene; and inorganic layers such as HSQ (hydroxysilsesquioxane), and these layers which have been made porous can be suitably used.

### Bump

The solder bump 5 may be, for example, a Pb-free solder. This embodiment employs a tin-silver solder. A component for the bump is not limited to it and may be, for example, a tin-bismuth or tin-zinc system. The solder bump 5 may have, for example, a coefficient of thermal expansion of 10 ppm/° C. or more and 25 ppm/° C. or less.

### Underfill

The underfill 6 fills the periphery of the solder bump 5 bonding the substrate 3 and the semiconductor chip 4.

A constituent material for the underfill 6 may be a liquid thermosetting resin or film thermosetting resin. Among these, a liquid thermosetting resin is preferable because it can efficiently fill a gap between the substrate 3 and the semiconductor chip 4. In this embodiment, the underfill 6 is made of a resin material having an elastic-modulus of 1.5 GPa or more and 12 GPa or less at room temperature.

Here, for determining an elastic modulus, a paste for the underfill 6 is shaped into a piece having a width of 10 mm, a length of about 150 mm and a thickness of 4 mm and then cured in an oven at 200° C. for 30 min, and for this sample, the elastic modulus is calculated from an initial slope in a stress-strain curve obtained by measurement using Tensilon testing machine at a rate of 1 mm/min under at a temperature lower than room temperature.

A resin material used for the underfill 6 may be selected from various materials. For example, epoxy resins, BT resins and cyanate resins can be used. As a cyanate resin, the novolac type cyanate resin as described for the substrate material can be suitably used.

A resin material constituting the underfill 6 preferably contain a polyfunctional epoxy resin. It allows a cured resin to have an improved crosslink density and a higher elastic modulus.

The underfill 6 may contain an inorganic filler such as silica particles. It allows for reduction of a coefficient of thermal expansion and further effective reduction of damages in the semiconductor chip 4 or the space between the semiconductor chip 4 and the substrate 3.

The underfill 6 may contain a coupling agent. It allows for improvement in adhesiveness of the bump or the inorganic filler to the underfill, and thus, reduction of a coefficient of thermal expansion and more effective reduction of damages in the semiconductor chip or the space between the semiconductor chip and the substrate 3. Examples of a coupling agent which can be used include silane coupling agents such as epoxysilanes and aminosilanes; and titanate coupling agents. These can be used in combination. The coupling agent may be used in a style that it is dispersed in a binder site in the underfill or that it adheres to the surface of an inorganic filler such as silica particles. Alternatively, these styles may be combined. For example, when silica particles are added, the silica surface can be pre-treated with a coupling agent.

The coefficient of thermal expansion (25° C. to a glass transition point) of the underfill is preferably 40 ppm/° C. or less, more preferably 30 ppm/° C. or less. It allows damages to be more effectively reduced in the low-k layer and in the periphery of the bump 5.

A coefficient of thermal expansion of the underfill can be determined as follows.

A liquid-injected sealing underfill material is cured at 150° C. for 120 min and then cut into a test piece of 5×5×10 mm. For this sample, a coefficient of thermal expansion was determined using Seiko TMA/SS120 under the conditions of a compressive load of 5 g and a temperature increase rate of 10° C./min.

There will be described the effects of this embodiment.

When αsig-x represents a coefficient of thermal expansion in a direction substantially parallel (X-direction) to the signal lines 312D1 in the signal line arrangement area A and αsig-y represents a coefficient of thermal expansion in a direction substantially orthogonal (Y-direction) to the signal lines, the dependence rate in the signal line direction of the coefficient of thermal expansion represented by the following equation is 25 or less.

Dependence rate in the signal line direction of the coefficient of thermal expansion=(|αsig-y−αsig-x|/αsig-x)×100

By making the dependence rate in the signal line direction of the coefficient of thermal expansion 25 or less, warpage in the surface of the substrate 3 can be reduced.

Reduction of warpage in the surface of the substrate 3 results in prevention of cracks in, for example, the interface between the bump 5 and the substrate 3 and improvement of reliability in connection with the semiconductor element 4.

Furthermore, αsig-x can be reduced by adjusting a dependence rate in the signal line direction of the coefficient of thermal expansion in the signal line arrangement area A to 25 or less and reducing an αsig-y to 2.5 ppm/° C. or more and 26 ppm/° C. or less. Thus, deviation of the signal line arrangement area A in directions orthogonal to and parallel to the signal lines can be reduced. Consequently, warpage in the surface of the substrate 3 can be more reliably reduced.

Furthermore, a coverage is high for the conductor interconnect layer 312B in the lower side of the substrate 3 to the insulating layer 311, and it can be supposed that the former strongly constrains the lower insulating layer 311 and a coefficient of thermal expansion is small in the lower part of the substrate 3. Consequently, the lower part of the substrate 3 is resistant to warpage due to heat history. Thus, in this embodiment, not only warpage in the surface of the substrate 3 but also warpage in the whole substrate 3 can be reliably reduced.

In this embodiment, the resin constituting the insulating layer 311 is a resin containing a cyanate, particularly a novolac-type cyanate, so that the dependence rate in the signal line direction of the coefficient of thermal expansion can be reliably reduced.

Conventionally, heating a substrate with a semiconductor element being mounted has sometimes caused warpage in the substrate, leading to cracks in, for example, an interface between a bump and the substrate.

Thus, it has been proposed that the periphery of the bump is filled with an underfill with a high elastic modulus, but an underfill with a high elastic modulus may cause damage on a low-k layer in the semiconductor element.

In contrast, a semiconductor device of this embodiment uses the substrate 3 with warpage being reduced, so that crack formation can be prevented in, for example, the interface between the bump 5 and the substrate 3. It can eliminate the necessity of using the underfill 6 with a high elastic modulus, and thus the underfill 6 with a low elastic modulus which is made of a resin material with an elastic modulus of 1.5 GPa or more and 12 GPa or less at room temperature, can be used, resulting in prevention of damage on a low-k layer in the semiconductor element.

The present invention is not limited to the above embodiment and variations and modifications can be encompassed within this invention as long as they can achieve the objectives of the present invention.

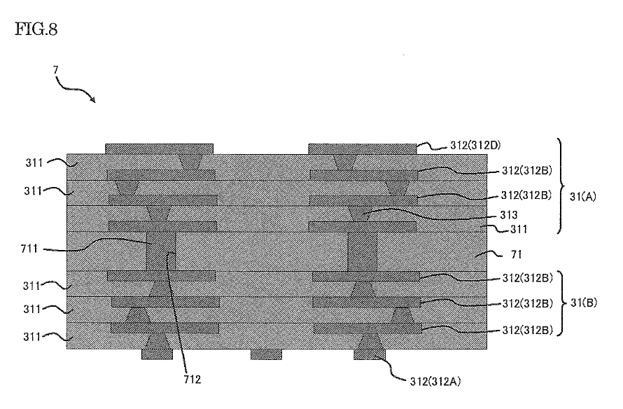

For example, in the above embodiment, the substrate 3 has only the build-up layer 31, but without limitation, it may be, for example, the substrate 7 as shown in FIG. 8. This substrate 7 may have a build-up layer 31 as described for the above embodiment and a core layer 71 having a throughhole 712 within which a conductor layer 711 is formed and the conductor layer 711 in the throughhole 712 is connected to the conductor interconnect layer 312.

Here, the core layer 71 has an insulating layer formed by laminating a prepreg (not shown). The prepreg is a glass cloth impregnated with a resin composition containing an epoxy resin, a cyanate resin (for example, a novolac-type cyanate resin) and so on. In the insulating layer, the throughhole 712 is formed.

In the substrate 7, a pair of the build-up layers 31 are arranged, sandwiching the core layer 71. The build-up layer 31 (build-up layer 31A) disposed in one side of the core layer 71 has the insulating layer 311, the conductor interconnect layer 312B and the conductor interconnect layer 312D. The build-up layer 31 (build-up layer 31B) disposed in the other side of the core layer 71 has the insulating layer 311, the conductor interconnect layer 312B and the conductor interconnect layer 312A.

A resin constituting the insulating layer in the core layer 71 may be, besides a cyanate resin, any other appropriate resin such as epoxy resins and BT resins.

Although a thickness of the substrate 3 is 800 μm or less, preferably 500 μm or less in the above embodiment, it may not be limited to the range and can exceed 800 μm.

Furthermore, although the substrate 3 and the semiconductor chip 4 are connected via the solder bump 5 in the above embodiment, the present invention is not limited to such a style. For example, the substrate 3 may be connected to the semiconductor chip 4 via a metal wire (junction).

Furthermore, although in the above embodiment, the insulating layer 311 is not reinforced by fiber, the present invention is not limited to such a style and the insulating layer 311 can contain, for example, glass fiber. Thus the dependence rate in the signal line direction of the coefficient of thermal expansion can be reliably 25 or less.

### EXAMPLES

Next, there will be described examples of the present invention.

### Example 1

In this example, a substrate substantially as described for the above embodiment was produced. Here, the substrate of this example is a substrate without a core layer, which has 8 conductor interconnect layers and 7 insulating layers.

Among the conductor interconnect layers, the uppermost conductor interconnect layer is as described for the conductor interconnect layer 312D in the above embodiment while the lowest conductor interconnect layer is as described for the conductor interconnect layer 312A. The other conductor interconnect layers are as described for the conductor interconnect layer 312B.

A process for producing the substrate was as described for the above embodiment.

The insulating layer was as shown in Table 1.

TABLE 1

| | | wt |
|---|---|---|
| Resin | Trade name and data | parts |
| Cyanate | Novolac type cyanate resin: | 25 |
| resin A | Lonza Japan Ltd., “Primaset PT-30”, | |
| | Weight average molecular weight: 700 | |
| Epoxy | Biphenyldimethylene type epoxy resin: | 25 |
| resin | Nippon Kayaku Co., Ltd., “NC-3000”, | |
| | Epoxy equivalent: 275, weight average | |
| | molecular weight: 2000 | |
| Phenoxy | Copolymer of a biphenyl epoxy resin and a | 5 |
| resin A | bisphenol-S epoxy resin having an end | |
| | epoxy group, | |
| | Japan Epoxy Resins, Co., Ltd., | |
| | “YX-8100H30”, | |
| | Weight average molecular weight: 30000 | |
| Phenoxy | Copolymer of a bisphenol-A type epoxy | 5 |
| resin B | resin and a bisphenol-F type epoxy resin | |
| | having an end expoxy group, | |
| | Japan Epoxy Resins, Co., Ltd., “Epicoat | |
| | 4275”, | |
| | Weight average molecular weight: 60000 | |
| Curing | Imidazole compound, | 0.4 |
| catalyst | Shikoku Chemicals Co., | |
| | “2-Phenyl-4,5-dihydroxymethylimidazole” | |
| Inorganic | Spherical fused silica, | 40 |
| filler | Admatechs Co., Ltd., “SO-25H”, | |
| | Average particle size: 0.5 μm | |
| Coupling | Epoxysilane coupling agent, | 0.2 |
| agent | Nippon Unicar Company Ltd., “A-187” | |

The process for producing an insulating layer is as follows.

In methyl ethyl ketone were dissolved and dispersed 25 parts by weight of cyanate resin A, 25 parts by weight of an epoxy resin, 5 parts by weight of phenoxy resin A, 5 parts by weight of phenoxy resin B and 0.4 parts by weight of a curing catalyst. To the mixture were added 40 parts by weight of an inorganic filler and 0.2 parts by weight of a coupling agent, and the mixture was stirred using a high-speed stirrer for 10 min to prepare a resin varnish with a solid content of 50% by weight.

The resin varnish prepared above was applied to one side of a PET (polyethylene terephthalate) film with a thickness of 38 μm using a comma coater such that a thickness of the insulating film after drying becomes 40 μm, and the product is dried in an oven at 160° C. for 10 min to prepare an insulating sheet with a base material, and after peeling the PET film off, an insulating layer was obtained.

### Example 2

A substrate was prepared as described in Example 1, except 30 parts by weight of cyanate resin A, 30 parts by weight of an epoxy resin and 30 parts by weight of an inorganic filler were used.

### Example 3

A substrate was prepared using a core layer containing a cyanate resin and an insulating layer and a conductor interconnect layer as described in Example 1 (FIG. 8). Here, the substrate of this example is a substrate having a core layer, and the core layer has a structure in which it is vertically symmetrically sandwiched by build-up layers. This substrate has a structure where three insulating layers are piled upwards and downwards centering the core layer, respectively, and thus there are 8 conductor interconnect layers and 6 insulating layers.

A process for producing the core layer is as follows.

In methyl ethyl ketone were dissolved at an ambient temperature 15% by weight (hereinafter, abbreviated as “%”) of a novolac-type cyanate resin (Lonza Japan Ltd., Primaset PT-60, weight-average molecular weight: about 2,600), 8% of a biphenyldimethylene type epoxy resin (Nippon Kayaku Co., Ltd., NC-3000P, epoxy equivalent: 275), 7% of a biphenyldimethylene type phenol resin (Meiwa Plastic Industries Ltd., MEH-7851-S, hydroxy equivalent: 203) and 0.3 parts by weight (hereinafter, abbreviated as “parts”) of an epoxysilane type coupling agent (Nippon Unicar Company Ltd., A-187) to 100 parts of an inorganic filler described later, and after adding 20% of a spherical fused silica SFP-10X (Denki Kagaku Kogyo Kabushiki Kaisha, average particle size: 0.3 μm) and 50% of a spherical fused silica SO-32R (Admatechs Co., Ltd., average particle size: 1.5 μm) as an inorganic filler, the resulting mixture was stirred using a high-speed stirrer for 10 min to prepare a resin varnish.

A glass woven fabric (a plain-woven base material made of E glass, thickness: 100 μm, warp weaving density 60/inch, woof weaving density: 58/inch, Nitto Boseki Co., Ltd., WEA-116E, a thermal expansion coefficient from room temperature to 250° C.: 6 ppm/° C.) was impregnated with the above resin varnish and heated in a heating furnace at 120° C. for 2 min to prepare a prepreg with a varnish solid content (a proportion of the resin and silica in the prepreg) of about 50%.

The above prepreg was combined with copper foils with a thickness of 12 μm on both sides and was pressed with heating under a pressure of 4 MPa and a temperature of 200° C. for 2 hours to provide a core layer with a thickness of 0.1 mm.

### Example 4

A substrate was prepared as described in Example 1, except that 27 parts by weight of cyanate resin A, 27 parts by weight of the epoxy resin and 36 parts by weight of inorganic filler were used.

### Example 5

A substrate was prepared using a core layer containing a cyanate resin and an insulating layer as described for Example 1 and an insulating layer and conductor interconnect layer described below (FIG. 8). Here, the substrate of this example is a substrate having a core layer, and the core layer has a structure in which it is vertically symmetrically sandwiched by build-up layers. This substrate has a structure where three insulating layers are piled upwards and downwards centering the core layer, respectively, and thus there are 8 conductor interconnect layers and 6 insulating layers. The insulating layers in the uppermost layer side in the substrate (2 layers) were the insulating layers described below and the other insulating layers were the insulating layers in Example 1 and the process was as described in Example 3.

The insulating layer in the uppermost layer side in the substrate (2 layers) were those produced as described below. In methyl ethyl ketone were dissolved 24% by weight of a cyanate resin (Lonza Japan Ltd., Primaset PT-30, weight-average molecular weight: about 2,600), 24% by weight of a biphenyldimethylene type epoxy resin (Nippon Kayaku Co., Ltd., NC-3000, epoxy equivalent: 275) as an epoxy resin, 11.8% by weight of a copolymer of a bisphenol-A type epoxy resin and a bisphenol-F type epoxy resin as a phenoxy resin having an end epoxy group (Japan Epoxy Resins, Co., Ltd., EP-4275, weight-average molecular weight 60,000), and 0.2% by weight of an imidazole compound (Shikoku Chemicals Corporation, “2-phenyl-4,5-dihydroxymethylimidazole”) as a curing catalyst. To the mixture were added 39.8% by weight of a spherical fused silica (Admatechs Co., Ltd., SO-25H, average particle size: 0.5 μm) as an inorganic filler and 0.2% by weight of an epoxysilane type coupling agent (Nippon Unicar Company Ltd., A-187), and the resulting mixture was stirred for 60 min using a high-speed stirrer to prepare a resin varnish with a solid content of 60% by weight.

The resin varnish obtained above was applied to one side of a PET (polyethylene terephthalate) film with a thickness of 38 μm such that a thickness after drying would become 14 μm, and the product was dried in an oven at 160° C. for 10 min to prepare an insulating sheet with a base material, and then two insulating sheets with a base material and a glass woven fabric (cloth type #1015, width: 360 mm, thickness: 15 μm, basis weight: 17 g/m²) were processed by a vacuum laminator and a hot-air drier to provide an insulating layer with a fiber base material.

The insulating layer thus obtained had a thickness of 35 μm (the first resin layer: 10 μm, the fiber base material: 15 μm, the second resin layer: 10 μm). Furthermore, the insulating layer had a structure where spaces between the fibers of the fiber base material were filled with the resin.

### Example 6

The process described in Example 5 was conducted except that the following varnish was used for the insulating layers in the uppermost side of the substrate (2 layers).

In methyl ethyl ketone were dissolved 24% by weight of a biphenyldimethylene type epoxy resin (Nippon Kayaku Co., Ltd., NC-3000, epoxy equivalent 275) and 17.5% by weight of a liquid bisphenol type epoxy resin (Dainippon Ink And Chemicals, Incorporated, 830S) as epoxy resins; 18% by weight of a phenoxy resin as a copolymer of a bisphenol-S epoxy resin having an end epoxy group (Japan Epoxy Resins, Co., Ltd., YX-8100, weight-average molecular weight: 30,000) as a phenoxy resin; 0.2% by weight of an imidazole compound (Shikoku Chemicals Corporation, “2-phenyl-4,5-dihydroxymethylimidazole”) as a curing catalyst. To the mixture were added 39.8% by weight of spherical fused silica (Admatechs Co., Ltd., SO-25H, average particle size: 0.5 μm) as an inorganic filler and 0.2% by weight of an epoxysilane type coupling agent (Nippon Unicar Company Ltd., A-187), and the resulting mixture was stirred for 60 min using a high-speed stirrer, to prepare a resin varnish with a solid content of 60% by weight.

The insulating layer thus obtained had a thickness of 35 μm (the first resin layer: 10 μm, the fiber base material: 15 μm, the second resin layer: 10 μm).

### Example 7

The process in Example 5 was conducted except that a glass woven fabric (cloth type #1037, thickness: 24 μm, basis weight: 24 g/m²) was used as a fiber base material and two types of thickness-adjusted sheets (12 μm and 18 μm) were used as an insulating sheet. A thickness of the insulating layer was 40 μm (the first resin layer: 5 μm, the fiber base material: 24 μm, the second resin layer: 11 μm).

### Example 8

The process in Example 5 was conducted except that among the insulating layers in the build-up layer, four layers other than the uppermost layer in the substrate were the insulating layers containing a fiber base material used in Example 5 and the other insulating layers were those used in Example 1.

### Example 9

The process in Example 5 was conducted except that all of the insulating layers in the build-up layer were the insulating layers containing the fiber base material used in Example 5.

### Comparative Example 1

The process in Example 1 was conducted except that the whole cyanate resin A was an epoxy resin.

### Evaluation of Examples 1 to 9 and Comparative Example 1

The substrates obtained in Examples and Comparative Example were evaluated for the following properties.

Using a laser speckle measuring apparatus (DNTEC ETTEMEYER, trade name: 3D-ESPI System Q-300), αsig-x and αsig-y were calculated for the signal line arrangement area.

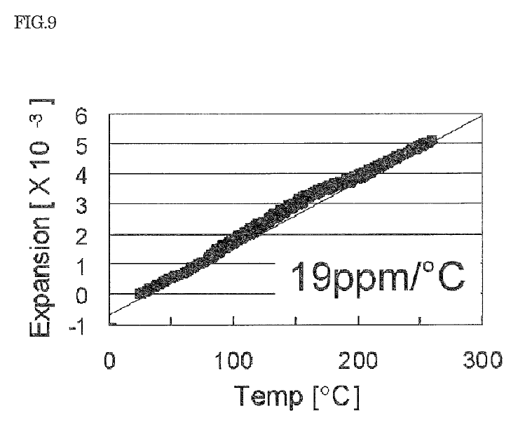

A coefficient of thermal expansion was calculated by approximating a graph of a temperature-displacement rate where a horizontal axis is a temperature and a vertical axis is a displacement rate in X-direction or Y-direction to a straight line connecting room temperature (25° C.) and 260° C. as shown in FIG. 9.

The results are shown in Table 2.

TABLE 2

| | | | Dependence rate in the |
|---|---|---|---|
| | | | signal line direction of a |
| | αsig-x | αsig-y | coefficient of thermal |
| | (ppm/° C.) | (ppm/° C.) | expansion |
| Example 1 | 19 | 20 | 5 |
| Example 2 | 20 | 25 | 25 |
| Example 3 | 19 | 20 | 5 |
| Example 4 | 20 | 23 | 15 |
| Example 5 | 17 | 16 | 6 |
| Example 6 | 16 | 17 | 6 |
| Example 7 | 16 | 17 | 6 |
| Example 8 | 17 | 16 | 6 |
| Example 9 | 17 | 16 | 6 |
| Comparative | 20 | 27 | 35 |
| Example 1 | | | |

In terms of a warpage amount of the above substrate, a displacement amount in a height direction was measured using a three-dimensional laser measuring equipment with variable temperature (Hitachi Technologies and Services, Ltd., Type LS220-MT100MT50), and the largest difference in a displacement amount was defined as a warpage amount. The measurement was conducted at an ambient temperature (25° C.). The symbols have the following meanings.

oo: warpage amount of 100 μm or less;

o: warpage amount of more than 100 μm and 150 μm or less;

x: warpage amount of more than 150 μm

The results are shown in Table 3.

TABLE 3

| | Warpage amount |
|---|---|
| Example 1 | ∘∘ |
| Example 2 | ∘ |
| Example 3 | ∘∘ |
| Example 4 | ∘∘ |
| Example 5 | ∘∘ |
| Example 6 | ∘∘ |
| Example 7 | ∘∘ |
| Example 8 | ∘∘ |
| Example 9 | ∘∘ |
| Comparative Example 1 | x |

A warpage amount in the substrate was reduced in Examples 1 to 9, whereas a warpage amount was increased in Comparative Example 1. It is confirmed that the present invention can reduce warpage in a substrate.

1. A substrate comprising a build-up layer in which resin-containing insulating layers and conductor interconnect layers are alternately laminated and said conductor interconnect layers are mutually connected through a conductor layer formed in a via-hole in said insulating layer,
wherein among said conductor interconnect layers, a conductor interconnect layer formed in the outermost surface side of the substrate includes a plurality of signal lines extending substantially in parallel with each other, and
when αsig-x represents a coefficient of thermal expansion in a direction substantially parallel to said signal lines in the signal line arrangement area having the plurality of signal lines as determined by a laser speckle method and αsig-y represents a coefficient of thermal expansion in a direction substantially orthogonal to said signal lines as determined by a laser speckle method, a dependence rate in the signal line direction of a coefficient of thermal expansion represented by the following equation is 25 or less.
Dependence rate in the signal line direction of the coefficient of thermal expansion=(|αsig-y−αsig-x|/αsig-x)×100

2. The substrate as claimed in claim 1, wherein said αsig-y is 2.5 ppm/° C. or more and 26 ppm/° C. or less.

3. The substrate as claimed in claim 1, wherein at least one of the insulating layers in said build-up layer includes a resin and a sheet base material supporting said resin.

4. The substrate as claimed in claim 3, wherein said insulating layer including said sheet base material is disposed in the outermost layer side of the substrate.

5. The substrate as claimed in claim 3, wherein said sheet base material has a thickness of 5 μm or more 30 μm or less.

6. The substrate as claimed in claim 1, wherein said resin for the insulating layer in said build-up layer includes a cyanate resin.

7. The substrate as claimed in claim 6, wherein said cyanate resin is a novolac-type cyanate resin.

8. The substrate as claimed in claim 1, wherein the substrate includes a core layer in which a throughhole filled with a conductor layer is formed within the insulating layer and said conductor layer in said throughhole is connected to said conductor interconnect layer in said build-up layer.

9. The substrate as claimed in claim 8, wherein the resin for said insulating layer in said core layer includes a cyanate resin.

10. The substrate as claimed in claim 1, wherein said substrate has a thickness of 800 μm or less.

11. A semiconductor device comprising
a substrate,
a semiconductor element mounted on said substrate,
a bump connecting said substrate with said semiconductor element, and an underfill filling the periphery of said bump;
wherein said substrate is the substrate as claimed in claim 1, and
said underfill is made of a resin material having an elastic modulus of 1.5 GPa or more and 12 GPa or less at room temperature.

12. The semiconductor device as claimed in claim 11, wherein said semiconductor element includes
a silicon substrate,
an insulating film containing a low-dielectric constant film with a specific dielectric constant of 3.3 or less which is formed on the silicon substrate, and
an interconnection formed in said insulating film.
